(19) United States
(12) Patent Application Publication
(10) Pub. No.: US 2026/0343742 A1
(43) Pub. Date: Oct. 29, 2026

(54) METHOD FOR MANUFACTURING IN-VEHICLE WIRING BOARD AND IN-VEHICLE WIRING BOARD

(71) Applicants: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(72) Inventor: Shinnosuke NAKAGUCHI, Yokkaichi-shi, Mie (JP)

(73) Assignees: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(21) Appl. No.: 19/114,545

(22) PCT Filed: Aug. 21, 2023
(86) PCT No.: PCT/JP2023/029995

§ 371 Date: Mar. 24, 2025

(30) Foreign Application Priority Data
Sep. 27, 2022 (JP) 2022-153733

(51) Int. Cl. H05K 1/11; H05K 1/02; H05K 1/181; H05K 3/00; H05K 3/40

(52) U.S. Cl. CPC H05K 1/116; H05K 1/0201; H05K 1/0296; H05K 1/181; H05K 3/0011; H05K 3/4007

(57) ABSTRACT

In a method for manufacturing an in-vehicle wiring board, a board body is used. The method for manufacturing an in-vehicle wiring board includes a selection step. In the selection step, according to a type of a vehicle in which an in-vehicle wiring board (e.g., the in-vehicle wiring board is to be mounted, at least one of the following is selected: whether or not a conductive portion is to be bonded to a plurality of land portions; a number of the conductive portions to be bonded to the plurality of land portions; and a destination to which a land portion is to be bonded via the conductive portion, among a plurality of second power paths insulated from a power path. With the method for manufacturing an in-vehicle wiring board, a current path using the power path is formed by applying a selection result of the selection step to the board body.

### CROSS-REFERENCE TO RELATED APPLICATIONS

This application is the U.S. national stage of PCT/JP2023/029995 filed on Aug. 21, 2023, which claims priority of Japanese Patent Application No. JP 2022-153733 filed on Sep. 27, 2022, the contents of which are incorporated herein.

### TECHNICAL FIELD

The present disclosure relates to a method for manufacturing an in-vehicle wiring board and an in-vehicle wiring board.

### BACKGROUND

JP 2010-28930A discloses a structure in which a portion of a current path is constituted by a connection member mounted on a board.

A current path may depend on the type, grade, and the like of the vehicle. When boards corresponding to the respective current paths are individually prepared, the number of types of the board may increase. Also, it is desired that the heat dissipation properties of the current path are improved.

An object of the present disclosure is to provide a technique with which a current path corresponding to the type of the vehicle can be easily realized while improving the heat dissipation properties using a common board on which a conductive portion can be mounted.

### SUMMARY

A method for manufacturing an in-vehicle wiring board according to the present disclosure is a method for manufacturing an in-vehicle wiring board using a board body, and the board body includes: a conductive layer having a wiring pattern; and an insulating layer having an insulating film covering a portion of the wiring pattern, a partial region of the wiring pattern is configured as a land portion not covered with the insulating film, the wiring pattern includes a power path in which a plurality of the land portions are formed, a conductive portion having heat dissipation properties is bondable to the land portions, the method includes a selection step of selecting, in accordance with a type of a vehicle in which the in-vehicle wiring board is to be mounted, at least one of the following: whether or not the conductive portion is to be bonded to the plurality of land portions; a number of the conductive portions to be bonded to the plurality of land portions; and a destination to which a land portion of the plurality of land portions is to be bonded via the conductive portion, among a plurality of second power paths insulated from the power path, and a current path using the power path is formed by applying a selection result of the selection step to the board body.

An in-vehicle wiring board according to the present disclosure is an in-vehicle wiring board including: a board body; and a conductive portion having heat dissipation properties, in which the board body includes: a conductive layer having a wiring pattern; and an insulating layer having an insulating film covering a portion of the wiring pattern, a partial region of the wiring pattern is configured as a land portion not covered with the insulating film, the wiring pattern has a power path in which a plurality of the land portions are formed, and the conductive portion satisfies at least one of a condition that the conductive portion is bonded to the plurality of land portions and a condition that the conductive portion is bonded to at least one of a plurality of second power paths insulated from the power path and a land portion of the plurality of land portions.

### ADVANTAGEOUS EFFECTS

With the technique according to the present disclosure, it is possible to realize a current path corresponding to the type of the vehicle while improving the heat dissipation properties using a common board on which a conductive portion can be mounted.

### BRIEF DESCRIPTION OF DRAWINGS

FIG. 1 is a partial plan view of a board body according to a first embodiment.

FIG. 2 is a partial plan view of an in-vehicle wiring board with no conductive portion connected.

FIG. 3 is a partial plan view of the in-vehicle wiring board with conductive portions bonded to one land row.

FIG. 4 is a partial plan view of the in-vehicle wiring board with conductive portions bonded to two land rows.

FIG. 5 is a cross-sectional view taken along line A-A in FIG. 3.

FIG. 6 is a partial plan view of a board body according to a second embodiment.

FIG. 7 is a partial plan view of an in-vehicle wiring board according to the second embodiment.

FIG. 8 is a partial plan view of a board body according to a third embodiment.

FIG. 9 is a partial plan view of an in-vehicle wiring board according to the third embodiment.

FIG. 10 is a diagram illustrating an example in which land portions and the conductive portions are arranged side by side in a second direction.

FIG. 11 is a diagram illustrating an example in which a plurality of conductive portions arranged shifted in the first direction are arranged close to each other in the second direction.

### DETAILED DESCRIPTION OF PREFERRED EMBODIMENTS

Hereinafter, embodiments of the present disclosure will be listed and illustrated.

In a first aspect, a method for manufacturing an in-vehicle wiring board using a board body, and the board body includes: a conductive layer having a wiring pattern; and an insulating layer having an insulating film covering a portion of the wiring pattern, a partial region of the wiring pattern is configured as a land portion not covered with the insulating film, the wiring pattern includes a power path in which a plurality of the land portions are formed, a conductive portion having heat dissipation properties is bondable to the land portions, the method includes a selection step of selecting, in accordance with a type of a vehicle in which the in-vehicle wiring board is to be mounted, at least one of the following: whether or not the conductive portion is to be bonded to the plurality of land portions; a number of the conductive portions to be bonded to the plurality of land portions; and a destination to which a land portion of the plurality of land portions is to be bonded via the conductive portion, among a plurality of second power paths insulated from the power path, and a current path using the power path is formed by applying a selection result of the selection step to the board body.

With the method for manufacturing the in-vehicle wiring board, it is possible to realize a current path corresponding to a plurality of types, depending on which is selected in the selection step. Further, since the conductive portion has heat dissipation properties, if the conductive portion is bonded to the land portions, the heat dissipation properties are improved. Accordingly, with the method for manufacturing the in-vehicle wiring board, it is possible to easily realize a current path corresponding to the type of the vehicle while improving the heat dissipation properties using a common board on which a conductive portion can be mounted.

In a second aspect, the method for manufacturing the in-vehicle wiring board according to the first aspect, in which in the selection step, in accordance with the type of the vehicle in which the in-vehicle wiring board is to be mounted, at least one of the following is selected: whether or not the conductive portion is to be bonded to the plurality of land portions; and the number of the conductive portions to be bonded to the plurality of land portions.

Since the cross-sectional area of the current path increases as the number of the conductive portions bonded thereto increases, the resistance value of the current path decreases and the maximum current value (allowable current value) at which a current can flow through the current path increases. That is, with the method for manufacturing the in-vehicle wiring board, it is possible to easily realize a current path with the allowable current value corresponding to the type of the vehicle.

In a third aspect, the method for manufacturing the in-vehicle wiring board according to the second aspect, in which the power path is provided with a plurality of land rows constituted by a plurality of the land portions arranged side by side, and in the selection step, when the number of the conductive portions to be bonded to the plurality of land portions is selected, the number of the land rows to which the conductive portions are to be bonded is selected.

The in-vehicle wiring board manufactured by the above-described method can be distinguished by the number of land rows to which the conductive portions are bonded. Therefore, with the in-vehicle wiring board manufactured by the above method, it is easy to visually identify the type to which the in-vehicle wiring board corresponds.

In a fourth aspect, the method for manufacturing the in-vehicle wiring board according to the second or the third aspect, in which the plurality of land portions are arranged side by side in a direction in which current flows, and when it is selected that the conductive portion is to be bonded to the land portions in the selection step, a bonding step of bonding the conductive portion to the plurality of land portions arranged side by side in the direction in which the current flows is performed.

With the in-vehicle wiring board manufactured by the above-described method, since the conductive portions are disposed along the direction in which the current flows, the current flowing through the power path easily flows into the conductive portions.

In a fifth aspect, the method for manufacturing the in-vehicle wiring board according to the first aspect, in which in the selection step, a destination to which the land portion is to be bonded via the conductive portion is selected from among the plurality of second power paths.

In the method for manufacturing the in-vehicle wiring board, at least one of a power supply source that supplies power to the power path and a power supply destination to which the power from the power path is supplied can be selected depending on which second power path is selected. That is, with the method for manufacturing an in-vehicle wiring board, at least one of the power supply source that supplies power to the power path and the power supply destination to which the power from the power path is supplied can be selected according to the type of the vehicle while improving the heat dissipation properties.

In a sixth aspect, the method for manufacturing the in-vehicle wiring board according to the fifth aspect, in which a second land portion is formed in each of the second power paths, the plurality of land portions include [[the]] land portions provided so as to individually correspond to the second land portions, and in the selection step, the land portion and the second land portion corresponding to the land portion are selected, and when the land portion and the second land portion corresponding to the land portion are selected in the selection step, a bonding step of bonding the conductive portion to the selected land portion and the second land portion is performed.

With the above method for manufacturing an in-vehicle wiring board, the conductive portion is bonded to the land portion and the second land portion corresponding to each other. This makes it easier to bond the land portion and the second land portion in a more appropriate positional relationship.

In a seventh aspect, the method for manufacturing the in-vehicle wiring board according to any one of the first through the sixth aspects, in which when the conductive portion is bonded to the land portions, the conductive portion is surface-mounted on the board body.

With the above method for manufacturing an in-vehicle wiring board, the back surface of the board body can be effectively used with ease as compared with a configuration in which the conductive portions are through-hole mounted.

In an eighth aspect, an in-vehicle wiring board including a board body; and a conductive portion having heat dissipation properties, wherein the board body includes: a conductive layer having a wiring pattern; and an insulating layer having an insulating film covering a portion of the wiring pattern, a partial region of the wiring pattern is configured as a land portion not covered with the insulating film, the wiring pattern has a power path in which a plurality of the land portions are formed, and the conductive portion satisfies at least one of a condition that the conductive portion is bonded to the plurality of land portions and a condition that the conductive portion is bonded to at least one of a plurality of second power paths insulated from the power path and a land portion of the plurality of land portions.

With the above in-vehicle wiring board, in the configuration where the conductive portion is bonded to the plurality of land portions, the cross-sectional area of the current path is increased due to the conductive portions in the configuration. As a result, the resistance value of the current path is decreased and the allowable current value is increased. Also, in the above in-vehicle wiring board, in the configuration where the conductive portion is bonded to at least one of the second power paths and the land portion, a current path connecting the power path to at least one of the second power paths is formed. Therefore, in the above in-vehicle wiring board, a common board on which conductive portions can be mounted is used, the heat dissipation properties are improved, and a current path corresponding to the type of vehicle is formed.

In a ninth aspect, the in-vehicle wiring board according to [8], in which the conductive portion is bonded to the plurality of land portions.

In the above in-vehicle wiring board, the cross-sectional area of the current path is increased due to the conductive portion. As a result, the resistance value of the current path is decreased and the allowable current value is increased.

In a tenth aspect, the in-vehicle wiring board according to [8], in which a second land portion is formed in each of the second power paths, each second land portion is disposed at a position corresponding to a land portion of the plurality of land portions, and the conductive portion is bonded to the land portion and the second land portion corresponding to each other.

In the above in-vehicle wiring board, a current path connecting a power path to at least one of the second power paths is formed by connecting the land portion and the second land portion corresponding to each other.

### First Embodiment

The following description relates to a method for manufacturing an in-vehicle wiring board using a board body 10.

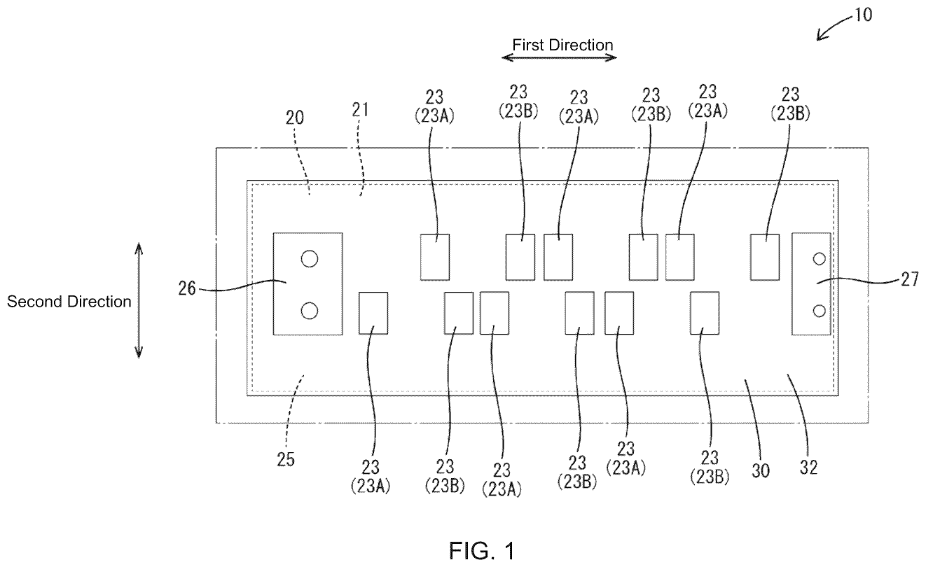

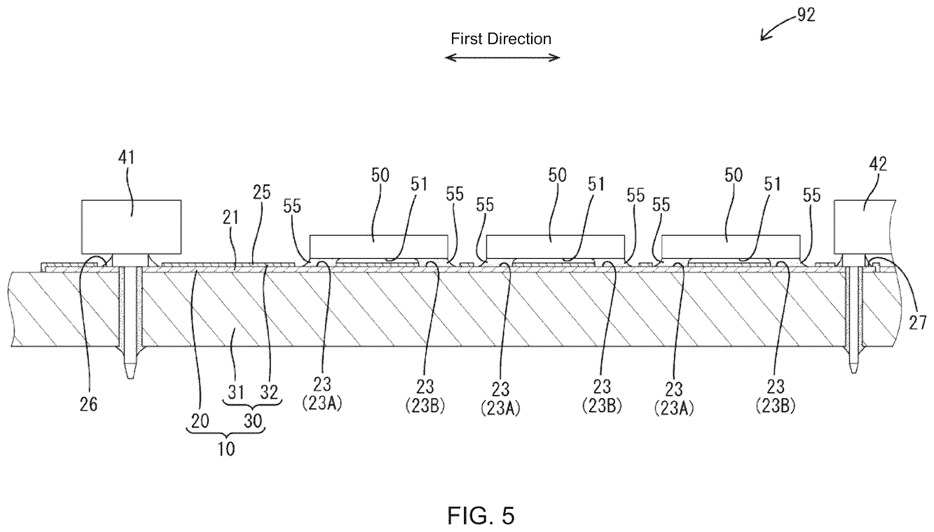

As shown in FIGS. 1 and 5, the board body 10 includes a conductive layer 20 and an insulating layer 30. The conductive layer 20 is constituted by a metal foil (e.g., copper foil), for example. The conductive layer 20 has a wiring pattern 21. The wiring pattern 21 has an elongated shape. The wiring pattern 21 includes an input-side electrical component 41 and an output-side electrical component 42. The wiring pattern 21 functions as an electrical path for supplying power input via the input-side electrical component 41 to the output-side electrical component 42 side. The input-side electrical component 41 is not particularly limited and may be a connector, a switch, a fuse, or another electrical component. The output-side electrical component 42 is not particularly limited and may be a connector, a switch, a fuse, or another electrical component.

As shown in FIG. 5, the insulating layer 30 has a base portion 31 and an insulating film 32. The base portion 31 has insulating properties and is constituted by resin, for example. The base portion 31 has a plate-like shape. The base portion 31 is thicker than the insulating film 32. The base portion 31 is disposed on one side of the board body 10 in the thickness direction relative to the conductive layer 20. In the following, the “thickness direction of the board body 10” is also referred to simply as the “thickness direction”. The conductive layer 20 (more specifically, the wiring pattern 21) is provided on the other side in the thickness direction in the base portion 31. The insulating film 32 covers a portion on the other side of the conductive layer 20 (more specifically, the wiring pattern 21) in the thickness direction. The insulating film 32 is configured as a solder resist, for example. The insulating film 32 has insulating properties, and is constituted by resin, for example.

As shown in FIG. 5, partial regions of the wiring pattern 21 are configured as land portions 23 that are not covered by the insulating film 32. Conductive portions 50 having heat dissipation properties are bondable to the land portions 23. The conductive portions 50 are members to be bonded to the land portions 23 with solder 55. Also, the conductive portions 50 are heat-dissipation members. The conductive portions 50 are not covered with resin. In other words, the surfaces of the conductive portions 50 are exposed without being covered with resin. Therefore, the conductive portions 50 can improve the heat dissipation properties compared to a jumper wire made of a covered wire. The conductive portions 50 are configured, for example, as bus bars (more specifically, chip bus bars). The conductive portions 50 are cuboids in this embodiment, but may be in another form. For example, the conductive portions 50 may be cubic or may include curved surfaces. The conductive portions 50 have an elongated shape. The conductive portions 50 each have an opposing surface 51 on one side thereof in the thickness direction. The opposing surfaces 51 are flat surfaces. The opposing surfaces 51 are disposed along the board body 10. The opposing surfaces 51 are bonded to the land portions 23 by the solder 55.

As shown in FIG. 1, the land portions 23 are surrounded by the insulating film 32. The land portions 23 have a rectangular shape. The wiring pattern 21 has a power path 25 having a plurality of land portions 23. The land portions 23 are arranged side by side in the first direction. The land portions 23 are arranged side by side in a straight line. The land portions 23 are arranged side by side in the direction in which the current flows. The direction in which the current flows is a direction along the first direction.

The power path 25 has a first connection portion 26 to which the input-side electrical component 41 is electrically connected and a second connection portion 27 to which the output-side electrical component 42 is electrically connected, as shown in FIG. 5. The first connection portion 26 and the second connection portion 27 are configured as through holes in the example shown in FIG. 5. The first connection portion 26 and the second connection portion 27 do not need to be through holes and may be lands, for example. The land portions 23 are disposed between the first connection portion 26 and the second connection portion 27. The “direction in which the current flows” is a direction from the first connection portion 26 toward the second connection portion 27.

As shown in FIGS. 1 and 5, the plurality of land portions 23 include land pairs each constituted by a pair of land portions 23. The land portions 23 in each pair are spaced apart from each other in the first direction. The conductive portions 50 are bonded to the pairs of land portions 23. Specifically, one end side in the longitudinal direction of the elongated conductive portion 50 is bonded to one land portion 23A, and the other end side thereof in the longitudinal direction is bonded to the other land portion 23B. According to this configuration, the amount of the solder 55 used can be reduced as compared with a configuration in which the entireties of the opposing surfaces 51 of the conductive portions 50 are bonded to the power path 25 by the solder 55.

As shown in FIG. 1, the plurality of land portions 23 include a plurality of land pairs. The power path 25 includes a configuration in which the plurality of land pairs are arranged side by side in the first direction. The power path 25 includes a configuration in which the plurality of land pairs are disposed shifted in the second direction.

As shown in FIG. 1, the power path 25 is provided with a plurality of land rows in which the plurality of land portions 23 are arranged side by side. The plurality of land rows are arranged side by side in a second direction orthogonal to the first direction and the thickness direction. The two land rows are provided in the example shown in FIG. 1. The number of the land portions 23 in each land row is the same. Each land row is constituted by a plurality of land pairs. The land pairs in the adjacent land rows are arranged shifted from each other in the first direction.

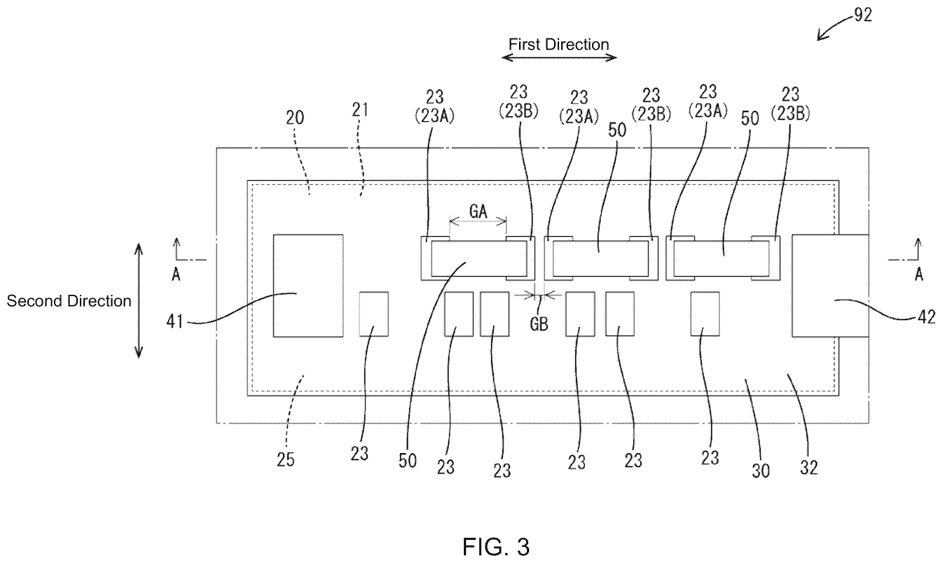

As shown in FIG. 3, a gap GA between one land portion 23A and the other land portion 23B in a pair of land portions 23 is longer than the length of each land portion 23 in the first direction and the length (width) of each land portion 23 in the second direction. The length of each land portion 23 in the first direction is shorter than the length (width) of each land portion 23 in the second direction. The gap GB between the land pairs that are adjacent in the first direction is shorter than the abovementioned gap GA, the length of the land portion 23 in the first direction, and the length (width) of the land portion 23 in the second direction. “The gap GB between the land pairs that are adjacent” means the gap between a land portion 23 that is in one land pair of the adjacent land pairs and is located toward the other land pair of the adjacent land pairs and a land portion 23 that is in the other land pair and is located toward the one land pair.

As shown in FIG. 3, the length of each conductive portion 50 in the longitudinal direction (first direction) is longer than the length of each land portion 23 in the first direction and the length (width) of each land portion 23 in the second direction. The length of each conductive portion 50 in the short direction (second direction) is longer than the length of each land portion 23 in the first direction, and shorter than the length (width) of each land portion 23 in the second direction.

When the conductive portions 50 are bonded to the plurality of land portions 23, the conductive portions 50 also form part of the current path formed by the power path 25. This increases the cross-sectional area of the current path formed by the power path 25. As the cross-sectional area of the current path increases, the resistance value of the current path decreases and the maximum current value (allowable current value) of the current that can flow through the current path increases.

The power path 25 also has a plurality of land pairs. As the number of conductive portions 50 bonded to the power path 25 increases, the cross-sectional area of the current path increases, the resistance value of the current path decreases, and the allowable current value increases.

For example, in a configuration where no conductive portion 50 is bonded to the land portions 23, the allowable current value is 30 A. In a configuration where the conductive portions 50 are bonded to “1” land row (specifically, bonded to each land pair in the “1” land row), the allowable current value is 60 A. In a configuration where the conductive portions 50 are bonded to “2” land rows (specifically, bonded to each land pair in the “2” land rows), the allowable current value is 100 A.

Thus, the allowable current value of the board body 10 is set according to the number of the bonded conductive portions 50. In addition, since the conductive portions 50 have heat dissipation properties, the heat dissipation properties are also improved by bonding the conductive portions 50.

### Method for Manufacturing In-Vehicle Wiring Board

The method for manufacturing an in-vehicle wiring board includes a preparation step and a selection step.

In the preparation step, the board body 10 is prepared. In the preparation step, the conductive portions 50 are also prepared as needed.

In the selection step, the number of conductive portions 50 bonded to the plurality of land portions 23 is selected according to the type of vehicle in which the in-vehicle wiring board is to be mounted. “Selecting the number of the conductive portions 50 to be bonded to the plurality of land portions 23” is synonymous with “selecting the number of land pairs to which the conductive portions 50 are to be bonded” in this embodiment.

“The type of vehicle” means the type classified by model, grade, destination, options, and the like. More specifically, “the type of vehicle” means the type that has a different allowable current value in the power path 25 depending on differences in the model, grade, destination, options, and the like. The “allowable current value in the power path 25” is the maximum current value of the current that can flow through the power path 25. The “type of vehicle” includes “type A”, “type B”, and “type C” in the present embodiment. A vehicle of type A is a vehicle that requires an allowable current value of 30 A. A vehicle of type B is a vehicle that requires an allowable current value of 60 A. A vehicle of type C is a vehicle that requires an allowable current value of 100 A.

“The number of the conductive portions 50 to be bonded to the plurality of land portions 23” includes “0”. The “number of the conductive portions 50 to be bonded to the plurality of land portions 23” is any one of “0”, “3”, and “6” in the present embodiment. In the selection step, the number of land rows to which the conductive portions 50 are to be bonded is selected when selecting the number of the conductive portions 50 to be bonded to the plurality of land portions 23. The “number of land rows to which the conductive portions 50 are to be bonded” includes “0”. The “number of land rows to which the conductive portions 50 are to be bonded” is one of “0”, “1”, and “2” in the present embodiment.

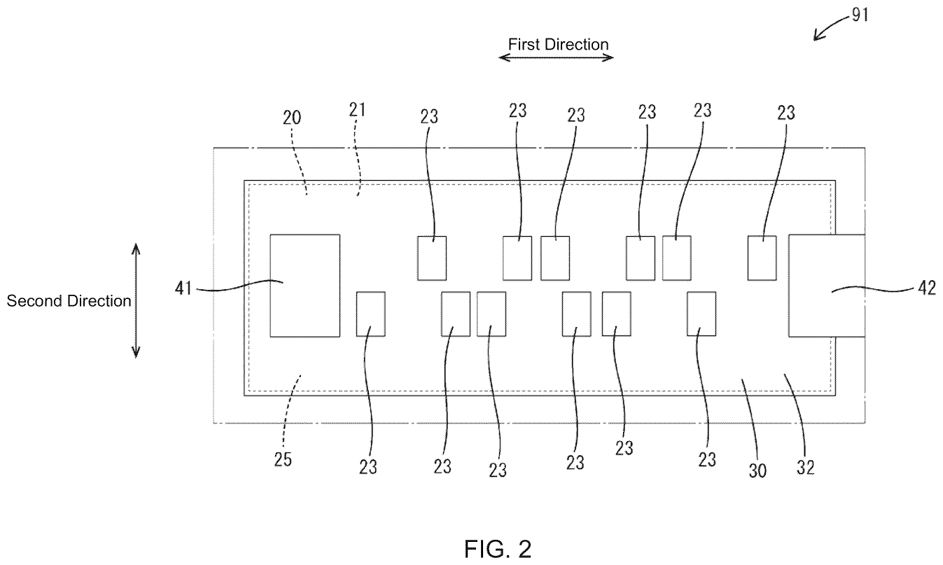

In the selection step, if the type of vehicle is the type A, “0” is selected as the “number of land rows to which the conductive portions 50 are to be bonded”. In other words, if the type of vehicle is type A, “0” is selected as the “number of conductive portions 50 to be bonded to the plurality of land portions 23”. In this case, as shown in FIG. 2, no conductive portion 50 is bonded to any of the land portions 23. In this manner, an in-vehicle wiring board 91 that includes a current path with an allowable current value of 30 A is manufactured.

Also, in the selection step, when the type of vehicle is type B, “1” is selected as the “number of land rows to which the conductive portions 50 are to be bonded”. In other words, if the type of vehicle is type B, “3” is selected as the “number of conductive portions 50 to be bonded to the plurality of land portions 23”. As described above, when it is selected that the conductive portions 50 are to be bonded to the land portions 23 in the selection step, the bonding step of bonding the conductive portions 50 to the plurality of land portions 23 is performed. In the bonding step, as shown in FIG. 3, the conductive portions 50 are bonded to the “1” land row. Specifically, in the bonding step, each conductive portion 50 is bonded to the corresponding land pair included in the “1” land row. As a result, the in-vehicle wiring board 92 including the current path having the 60 A of the allowable current value is manufactured.

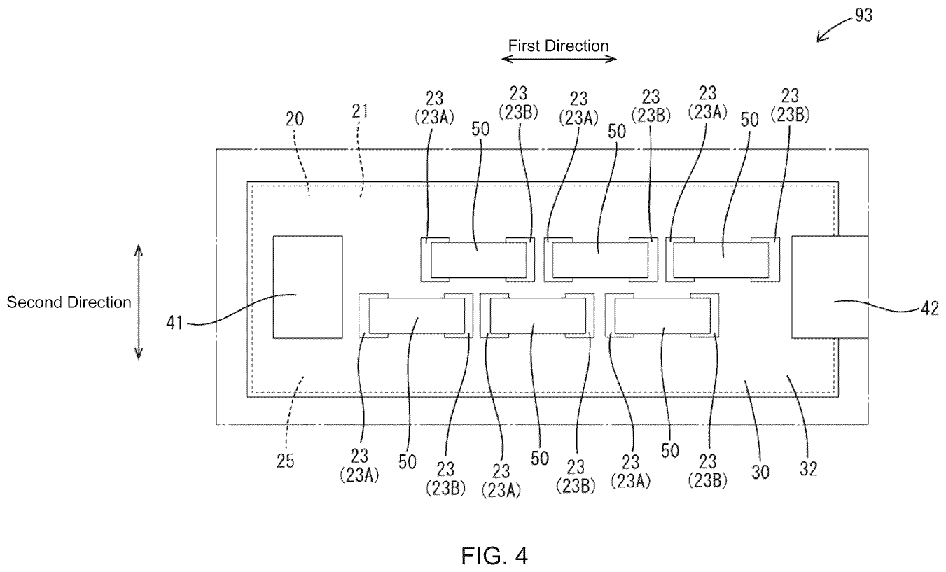

Also, in the selection step, when the type of vehicle is type C, “2” is selected as “the number of land rows to which the conductive portions 50 are bonded”. That is, when the type of vehicle is type C, “6” is selected as “the number of the conductive portions 50 to be bonded to the plurality of land portions 23”. As described above, when it is selected that the conductive portions 50 are to be bonded to the land portions 23 in the selection step, the bonding step of bonding the conductive portions 50 to the plurality of land portions 23 is performed. In the bonding step, as shown in FIG. 4, the conductive portions 50 are bonded to the “2” land rows. Specifically, in the bonding step, each conductive portion 50 is bonded to the corresponding land pairs included in the “2” land rows. As a result, the in-vehicle wiring board 93 including the current path having the allowable current value of the 100 A is manufactured.

In the bonding step, the conductive portions 50 are bonded to the land portions 23 by the solder 55. The soldering is, for example, reflow soldering. The conductive portions 50 are surface-mounted on the board body 10.

As illustrated in FIGS. 2 to 5, the input-side electrical component 41 is connected to the first connection portion 26 of the in-vehicle wiring board 91, 92, or 93 by soldering or the like. The output-side electrical component 42 is connected to the second connection portion 27 of the in-vehicle wiring board 91, 92, or 93 by soldering or the like.

### Examples of Effects

In the method for manufacturing the in-vehicle wiring board according to the first embodiment, by selecting the number of the conductive portions 50 to be bonded to the plurality of land portions 23 in the selection step, it is possible to realize a current path having an allowable current value corresponding to a plurality of types. In addition, since the conductive portions 50 have heat dissipation properties, when the conductive portions 50 are bonded to the land portions 23, the heat dissipation properties are improved. More specifically, since the conductive portions 50 are not covered with resin, the heat dissipation properties are improved as compared with a configuration in which jumper wires formed of coated wires are bonded. Therefore, the method for manufacturing an in-vehicle wiring board can easily realize a current path corresponding to the type of the vehicle while improving the heat dissipation properties by using the common board on which the conductive portions 50 can be mounted.

In the method for manufacturing an in-vehicle wiring board of the first embodiment, the conductive portions 50 are bonded to the selected number of land rows. The in-vehicle wiring board manufactured by the above method can be distinguished by the number of land rows to which the conductive portions 50 are bonded. In this manner, with the in-vehicle wiring board manufactured by the above method, it is easy to visually identify the type to which the in-vehicle wiring board corresponds.

In addition, in the in-vehicle wiring board manufactured by the above method, since the conductive portions 50 are disposed along the direction in which the current flows, the current flowing through the power path 25 easily flows into the conductive portions 50.

In addition, in the in-vehicle wiring board manufactured by the above method, since the conductive portions 50 are surface-mounted on the board body 10, the back surface of the board body 10 can be effectively used with ease as compared with a configuration in which the conductive portions are through-hole mounted.

In the in-vehicle wiring boards 92 and 93 shown in FIGS. 3 and 4, since the conductive portions 50 are bonded to the plurality of land portions 23, the cross-sectional area of the current path formed by the power path 25 is increased. As a result, the resistance value of the current path decreases, and the allowable current value increases. Therefore, in the in-vehicle wiring board 92, the common board on which the conductive portions 50 can be mounted is used, the heat dissipation properties are improved, and the current path corresponding to the type of vehicle is formed.

### Second Embodiment

In a second embodiment, a configuration in which the conductive portions are bonded to the land portions in the power path and at least one second power path among a plurality of second power paths disposed on the input side will be described.

The following description relates to a method for manufacturing the in-vehicle wiring board of the second embodiment using a board body 210.

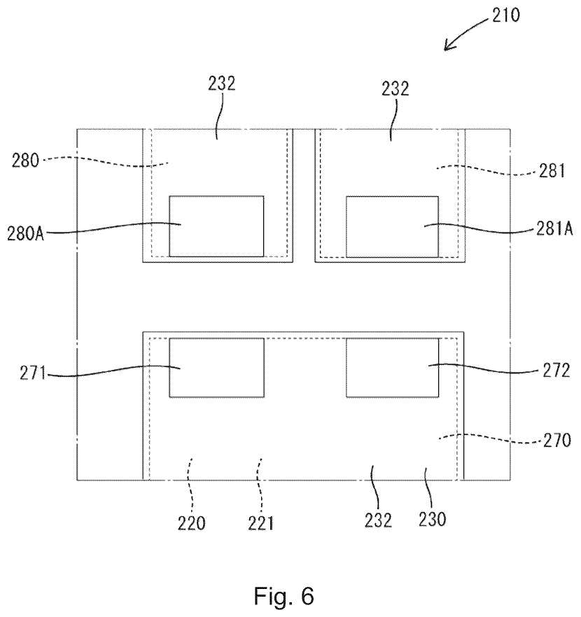

As shown in FIG. 6, the board body 210 includes a conductive layer 220 and an insulating layer 230. The conductive layer 220 is constituted by, for example, a metal foil (for example, a copper foil). The conductive layer 220 includes a wiring pattern 221. The insulating layer 230 includes the base portion 31 (see FIG. 5) described in the first embodiment, and insulating films 232. The insulating films 232 are configured as, for example, solder resists. The insulating films 232 have insulating properties and are constituted by, for example, a resin.

The wiring pattern 221 includes a first power path 270 and a plurality of second power paths 280 and 281. The first power path 270 is spaced apart from the second power paths 280 and 281. The first power path 270 is insulated from each of the second power paths 280 and 281 in a state where no conductive portion 50 is bonded. The second power paths 280 and 281 are spaced apart from each other. The second power paths 280 and 281 are insulated from each other.

Partial regions of the wiring pattern 221 are configured as first land portions 271 and 272 that are not covered with the insulating film 232. A plurality of first land portions 271 and 272 are formed on the first power path 270. The first land portions 271 and 272 are spaced apart from each other.

A partial region of the wiring pattern 221 is configured as a second land portion 280A that is not covered with the insulating film 232. The second land portion 280A is formed in the second power path 280.

A partial region of the wiring pattern 221 is configured as a second land portion 281A that is not covered with the insulating film 232. The second land portion 281A is formed in the second power path 281. That is, the second land portions are respectively formed in the second power paths.

The first land portions 271 and 272 include the first land portions corresponding to the respective second land portions. Specifically, the first land portion 271 is disposed at a position corresponding to the second power path 280 (specifically, the second land portion 280A). The first land portion 271 can be bonded to the second power path 280 (specifically, the second land portion 280A) via the conductive portion 50. The first land portion 272 is disposed at a position corresponding to the second power path 281 (specifically, the second land portion 281A). The first land portion 272 can be bonded to the second power path 281 (specifically, the second land portion 281A) via the conductive portion 50. That is, the second power paths 280 and 281 (specifically, the second land portions 280A and 281A) correspond to options of “destinations to which the first land portions 271 and 272 are to be bonded via the conductive portions 50”.

Mutually different powers are respectively supplied to the second power paths 280 and 281. The mutually different powers may be electric powers supplied from different batteries, or may be powers from a common battery that are made different by voltage conversion or the like.

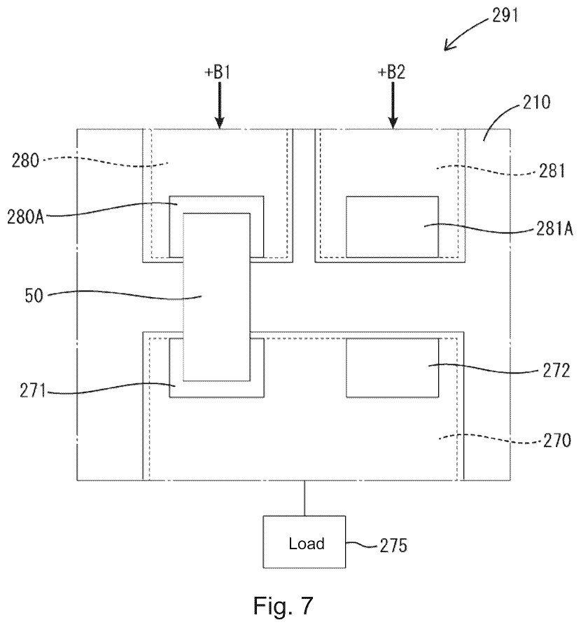

As shown in FIG. 7, for example, a first voltage (+B1 voltage) is applied to the second power path 280. For example, a second voltage (+B2 voltage) is applied to the second power path 281. When the first land portion 271 is bonded to the second power path 280 (specifically, the second land portion 280A) via the conductive portion 50, power is supplied from the second power path 280 to the first power path 270. That is, the first voltage (+B1 voltage) is applied to the first power path 270. When the first land portion 272 is bonded to the second power path 281 (specifically, the second land portion 281A) via the conductive portion 50, power is supplied from the second power path 281 to the first power path 270. That is, the second voltage (+B2 voltage) is applied to the first power path 270. The first power path 270 supplies the power supplied from the second power path to the load 275 side. The type of the load is not particularly limited.

### Method for Manufacturing In-Vehicle Wiring Board

The method for manufacturing an in-vehicle wiring board includes a preparation step and a selection step.

In the preparation step, the board body 210 and the conductive portions 50 are prepared.

In the selection step, the destination to which the first land portion 271 or 272 is to be bonded via the conductive portion 50 is selected from the plurality of second power paths 280 and 281 in accordance with the type of the vehicle in which the in-vehicle wiring board is to be mounted. As described above, the first land portions are disposed at positions corresponding to the respective second land portions. Therefore, in the selection step, one of the plurality of first land portions 271 and 272 and the second land portion corresponding to the first land portion are selected.

When the first land portion and the second land portion corresponding to the first land portion are selected in the selection step, a bonding step of bonding the conductive portions 50 to the selected first land portion and second land portion is performed.

For example, when the first land portion 271 and the second land portion 280A are selected in the selection step, the conductive portion 50 is bonded to the first land portion 271 and the second land portion 280A. In this case, an in-vehicle wiring board 291 in which the second power path 280 is connected to the first power path 270 is manufactured (see FIG. 7).

When the first land portion 272 and the second land portion 281A are selected in the selection step, the conductive portion 50 is bonded to the first land portion 272 and the second land portion 281A. In this case, an in-vehicle wiring board (not shown) in which the second power path 281 is connected to the first power path 270 is manufactured.

### Examples of Effects

In the method for manufacturing an in-vehicle wiring board according to the second embodiment, the power supply source that supplies power to the first power path 270 can be selected by the selection of the second power path in the selection step. In addition, since the conductive portion 50 has heat dissipation properties, the heat dissipation properties are improved. Therefore, with the method for manufacturing an in-vehicle wiring board of the second embodiment, it is possible to easily realize the current path according to the type of the vehicle while improving the heat dissipation properties by using the common board on which the conductive portion 50 can be mounted.

In addition, the plurality of first land portions 271 and 272 include the first land portions respectively provided corresponding to the second power paths 280 and 281 (specifically, the second land portions 280A and 281A). In the bonding step, the conductive portion 50 is bonded to the first land portion and the second land portion corresponding to the first land portion. Therefore, in the method for manufacturing the in-vehicle wiring board of the second embodiment, the conductive portion 50 is bonded to the first land portion and the second land portion disposed at positions corresponding to each other. For this reason, it is easy to bond the first land portion and the second land portion in a more appropriate positional relationship.

In addition, in the in-vehicle wiring board 291 shown in FIG. 7, a current path in which the first power path 270 is connected to any one of the second power paths is formed by connecting the first land portion and the second land portion disposed in a mutually corresponding positional relationship.

### Third Embodiment

In a third embodiment, a configuration in which the conductive portion is bonded to the land portion of the power path and at least one of the plurality of second power paths disposed on the output side will be described.

The following description relates to a method for manufacturing an in-vehicle wiring board of the third embodiment using a board body 310.

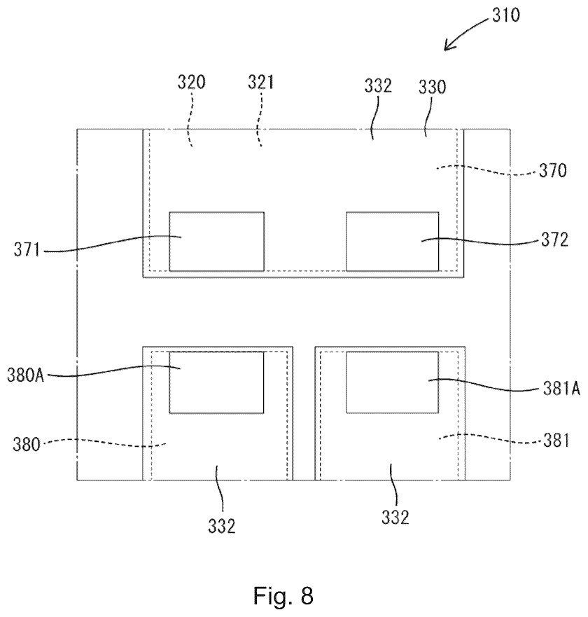

As shown in FIG. 8, the board body 310 includes a conductive layer 320 and an insulating layer 330. The conductive layer 320 is constituted by, for example, a metal foil (e.g., a copper foil). The conductive layer 320 has a wiring pattern 321. The insulating layer 330 includes the base portion 31 described in the first embodiment (see FIG. 5) and insulating films 332. The insulating films 332 are configured as, for example, solder resists. The insulating films 332 have insulating properties and are made of, for example, a resin.

The wiring pattern 321 includes a first power path 370 and a plurality of second power paths 380 and 381. The first power path 370 is spaced apart from the second power paths 380 and 381. The first power path 370 is insulated from each of the second power paths 380 and 381 in a state where no conductive portion 50 is bonded. The second power paths 380 and 381 are spaced apart from each other. The second power paths 380 and 381 are insulated from each other.

Partial regions of the wiring pattern 321 are configured as first land portions 371 and 372 that are not covered with the insulating film 332. A plurality of first land portions 371 and 372 are formed on the first power path 370. The first land portions 371 and 372 are spaced apart from each other.

A partial region of the wiring pattern 321 is configured as a second land portion 380A that is not covered with the insulating film 332. A second land portion 380A is formed in the second power path 380.

A partial region of the wiring pattern 321 is configured as a second land portion 381A that is not covered with the insulating film 332. A second land portion 381A is formed in the second power path 381. That is, the second land portions are respectively formed in the second power paths.

The plurality of first land portions 371 and 372 include first land portions corresponding to the respective second land portions. Specifically, the first land portion 371 is disposed at a position corresponding to the second power path 380 (specifically, the second land portion 380A). The first land portion 371 can be bonded to the second power path 380 (specifically, the second land portion 380A) via the conductive portion 50. The first land portion 372 is disposed at a position corresponding to the second power path 381 (specifically, the second land portion 381A). The first land portion 372 can be bonded to the second power path 381 (specifically, the second land portion 381A) via the conductive portion 50.

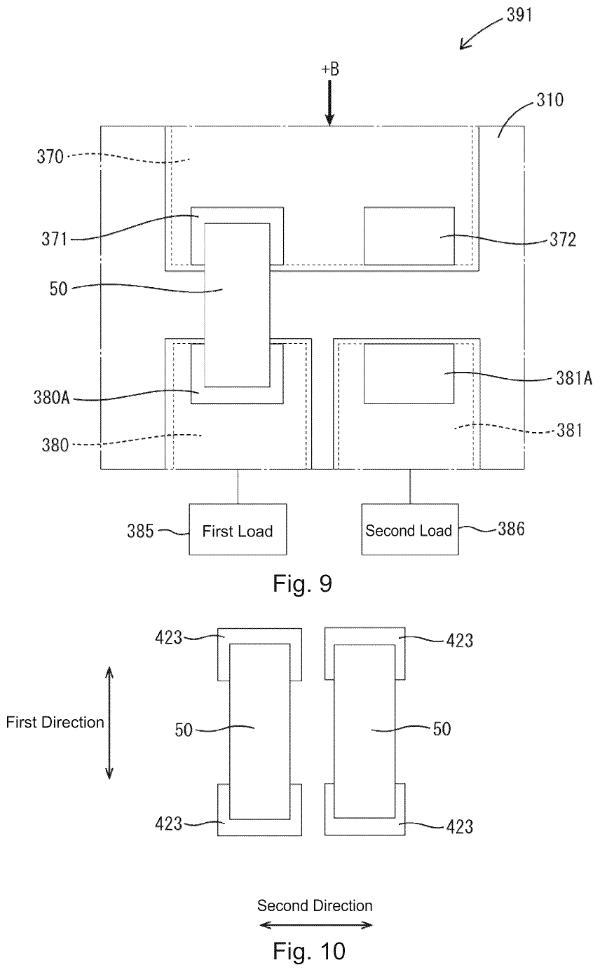

As shown in FIG. 9, different loads can be respectively connected to the second power paths 380 and 381. For example, a first load 385 can be connected to the second power path 380, and a second load 386 can be connected to the second power path 381. The types of the first load 385 and the second load 386 are not particularly limited.

As shown in FIG. 9, the +B voltage is applied to the first power path 370. When the first land portion 371 is bonded to the second power path 380 (specifically, the second land portion 380A) via the conductive portion 50, power is supplied from the first power path 370 to the second power path 380. That is, the +B voltage is applied to the second power path 380. When the first land portion 372 is bonded to the second power path 381 (specifically, the second land portion 381A) via the conductive portion 50, power is supplied from the first power path 370 to the second power path 381. That is, a predetermined voltage (for example, the +B voltage) is applied to the second power path 381.

### Method for Manufacturing In-vehicle Wiring Board

A method for manufacturing an in-vehicle wiring board includes a preparation step and a selection step.

In the preparation step, the board body 310 and the conductive portions 50 are prepared.

In the selection step, destinations to which the first land portions 371 and 372 are to be bonded via the conductive portions 50 are selected from the plurality of second power paths 380 and 381, according to the type of the vehicle in which the in-vehicle wiring board is to be mounted. In the present embodiment, “only the second power path 380” and “both the second power paths 380 and 381” are prepared as options of “destinations to which the first land portion 371 and 372 are to be bonded”.

If “only the second power path 380” is selected in the selection step, a bonding step of bonding the conductive portion 50 to the second land portion 380A of the second power path 380 and the first land portion 371 is performed. In this case, an in-vehicle wiring board (see FIG. 9) in which the first power path 370 is connected to the second power path 380 is manufactured.

If “both the second power paths 380 and 381” is selected in the selection step, the bonding step of bonding the conductive portion 50 to the second land portion 380A of the second power path 380 and the first land portion 371 and bonding the conductive portion 50 to the second land portion 381A of the second power path 381 and the first land portion 372 is performed. In this case, an in-vehicle wiring board (not shown) in which the first power path 370 is connected to each of the plurality of second power paths 380 and 381 is manufactured.

### Examples of Effects

In the method for manufacturing an in-vehicle wiring board according to the third embodiment, a power supply destination to which power is supplied from the first power path 370 can be selected by the selection of the second power path in the selection step. Moreover, since the conductive portion 50 has heat dissipation properties, the heat dissipation properties are improved. Therefore, with the method for manufacturing the in-vehicle wiring board of the third embodiment, it is possible to easily realize the current path according to the type of the vehicle while improving the heat dissipation properties by using the common board on which the conductive portions 50 can be mounted.

In addition, the plurality of first land portions 371 and 372 include the first land portions that correspond to the respective second power paths 380 and 381 (specifically, the second land portions 380A and 381A). In the bonding step, the conductive portions 50 are respectively bonded to the first land portions and the second land portions corresponding to the first land portions. Therefore, in the method for manufacturing the in-vehicle wiring board of the third embodiment, the conductive portion 50 is bonded to the first land portion and the second land portion disposed at positions corresponding to each other. Therefore, the first land portion and the second land portion are easily bonded to each other in a more appropriate positional relationship.

In addition, in the in-vehicle wiring board 391 shown in FIG. 9, the current path in which the first power path 370 is connected to a desired second power path is formed by connecting the first land portion and the second land portion disposed in a mutually corresponding positional relationship.

### Other Embodiments

The present disclosure is not limited to the embodiments described by way of the above descriptions and drawings. For example, the features of the above-described or later-described embodiments can be combined in any manner as long as they do not contradict each other. In addition, any of the features of the above-described or later-described embodiments may be omitted unless explicitly stated as required. Furthermore, the above-described embodiments may be modified as follows.

In each of the above-described embodiments, the conductive portions are surface-mounted on the board body, but the conductive portions may be through-hole mounted.

In the first embodiment, the number of the conductive portions to be bonded to the plurality of land portions is selected in the selection step, but whether or not the conductive portions are to be bonded to the plurality of land portions may be selected in the selection step.

In the first embodiment, the pair of land portions are disposed along the direction in which the current flows, but there is no limitation to this configuration. For example, a straight line connecting the pair of land portions may be inclined relative to the direction in which the current flows. From the viewpoint of making it easy for current to flow through the conductive portion bonded to the pair of land portions, the inclination angle relative to the direction in which the current flows is preferably 45 degrees or less.

Although the two land rows are used in the first embodiment, one or three or more land rows may be used.

Although the number of the conductive portions to be connected is selected for each land row in the above-described first embodiment, another configuration may be adopted. For example, the number of the conductive portions to be connected may be selected regardless of the land row.

Although the conductive portion is bonded to the two land portions in the first embodiment, the conductive portion may be bonded to three or more land portions.

In the first embodiment, the plurality of land portions and the plurality of conductive portions disposed to be shifted in the second direction are shifted from each other in the first direction, but another configuration may be adopted. For example, as shown in FIG. 10, a plurality of land portions 423 and the conductive portions 50 may be arranged side by side in the second direction.

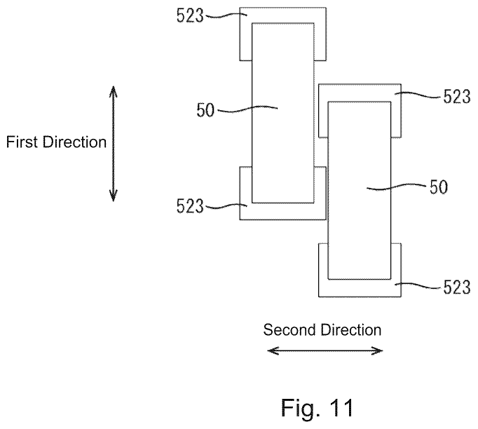

In the first embodiment, the positional relationship between the conductive portions and the land portions may be as shown in FIG. 11. That is, the two conductive portions 50 may be disposed at positions overlapping each other in the second direction and shifted from each other in the first direction, and the land portion 523 bonded to one conductive portion 50 and the land portion 523 bonded to the other conductive portion 50 may be disposed at positions overlapping each other in the first direction. According to this configuration, it is easy to reduce the gaps between the conductive portions 50 in the second direction.

The embodiments disclosed here are to be considered in all respects as illustrative and not limiting. The present disclosure is not intended to be limited to these embodiments disclosed here, and is intended to include all modifications within the scope indicated by the claims or the scope of equivalents of the claims.

1. A method for manufacturing an in-vehicle wiring board using a board body,
wherein the board body includes:
a conductive layer having a wiring pattern; and
an insulating layer having an insulating film covering a portion of the wiring pattern,
a partial region of the wiring pattern is configured as a land portion not covered with the insulating film,
the wiring pattern includes a power path in which a plurality of the land portions are formed,
a conductive portion having heat dissipation properties is bondable to the land portions, each of which is surrounded by the insulating film,
the method includes a selection step of selecting, in accordance with a type of a vehicle in which the in-vehicle wiring board is to be mounted, at least one of the following: whether or not the conductive portion is to be bonded to the plurality of land portions; and a number of the conductive portions to be bonded to the plurality of land portions; and
a current path using the power path is formed by applying a selection result of the selection step to the board body,
the plurality of land portions are arranged side by side in a direction in which current flows, and
when it is selected that the conductive portion is to be bonded to the land portions in the selection step, a bonding step of bonding the conductive portion to the plurality of land portions arranged side by side in the direction in which the current flows is performed.

2. The method for manufacturing an in-vehicle wiring board according to claim 1, wherein
the power path is provided with a plurality of land rows constituted by a plurality of the land portions arranged side by side, and
in the selection step, when the number of the conductive portions to be bonded to the plurality of land portions is selected, the number of the land rows to which the conductive portions are to be bonded is selected.

3. The method for manufacturing an in-vehicle wiring board according to claim 1, wherein when the conductive portion is bonded to the land portions, the conductive portion is surface-mounted on the board body.

4. An in-vehicle wiring board comprising:
a board body; and
a conductive portion having heat dissipation properties,
wherein the board body includes:
a conductive layer having a wiring pattern; and
an insulating layer having an insulating film covering a portion of the wiring pattern,
a partial region of the wiring pattern is configured as a land portion not covered with the insulating film,
the wiring pattern has a power path in which a plurality of the land portions are formed,
each of the land portions is surrounded by the insulating film,
a plurality of the land portions are arranged side by side in a direction in which current flows,
the conductive portion is joined to the plurality of land portions arranged side by side in the direction in which the current flows.

5. The method for manufacturing an in-vehicle wiring board according to claim 2, wherein when the conductive portion is bonded to the land portions, the conductive portion is surface-mounted on the board body.
